(19) United States
(12) Patent Application Publication
(10) Pub. No.: US 2013/0140172 A1
(43) Pub. Date: Jun. 6, 2013

(54) IN-LINE SPUTTERING APPARATUS

(71) Applicant: CHING-CHOU CHANG, Tu-Cheng (TW)

(72) Inventor: CHING-CHOU CHANG, Tu-Cheng (TW)

(73) Assignee: HON HAI PRECISION INDUSTRY CO., LTD., Tu-Cheng (TW)

(21) Appl. No.: 13/598,887

(22) Filed: Aug. 30, 2012

(30) Foreign Application Priority Data
Dec. 6, 2011 (TW) 100144766

(51) Int. Cl. C23C 14/34

(52) U.S. Cl. 204/298.11

(57) ABSTRACT

An in-line sputtering apparatus includes a loading chamber, a deposition chamber and an unloading chamber. The deposition chamber is positioned between the loading chamber and the unloading chamber. The deposition chamber includes at least one deposition room, a plurality of electrodes and at least one target assembly. Each deposition room defines a deposition area. A plurality of electrodes is positioned on opposite sidewalls of the deposition room, and the electrodes on the same sidewall are equidistantly spaced from each other. Each target assembly is positioned in one deposition room, which includes a plurality of targets and at least one shielding member. Each target is mounted on one electrode and away from the deposition area, a gap is formed between each two adjacent targets, each shielding member is positioned toward one gap for shielding sputtering of atoms from the edges of two neighboring targets.

### BACKGROUND

1. Technical Field

The present disclosure generally relates to sputtering apparatuses, and particularly to an in-line sputtering apparatus.

2. Description of Related Art

Vacuum sputtering technology is used extensively in the semiconductor industry, optoelectronic industry and other industry fields to form thin films of various materials. In-line sputtering apparatuses are applied widely now, because of lower cost of the vacuum sputtering process than traditional batch type and wafer type apparatuses. An in-line sputtering apparatuses usually includes a loading chamber, a deposition chamber and an unloading chamber arranged in that order. Targets are aligned in the deposition chamber along a transferring direction of substrates. When the substrate reaches the gaps between two neighboring targets, atoms from the edges of neighboring two targets will collide and both types of atoms from different targets will be deposited upon the substrate. Then the thickness of some part of the substrate will be greater than other parts due to this phenomenon. This results in the thickness of the film being not uniform.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 shows a top plan view of an embodiment of an in-line sputtering apparatus with a deposition room.

FIG. 2 shows a sectional, isometric view of a deposition room of the in-line sputtering apparatus of FIG. 1.

### DETAILED DESCRIPTION

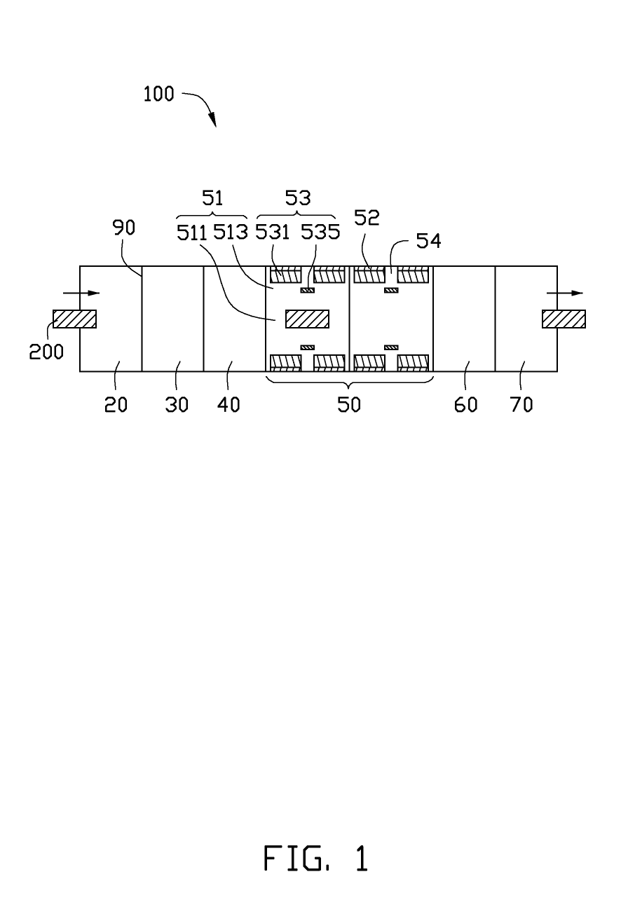

Referring to FIG. 1, an embodiment of an in-line sputtering apparatus 100 used for depositing thin film of a material on a plurality of substrates 200 is shown. The in-line sputtering apparatus 100 includes a loading chamber 20, a pre-process chamber 30, a first buffer chamber 40, a deposition chamber 50, a second buffer chamber 60 and an unloading chamber 70 arranged in that order. The in-line sputtering apparatus 100 further includes a plurality of movable gates 90 positioned between each two adjacent chambers as described above. In the illustrated embodiment, the pre-process chamber 30, the first buffer chamber 40, the deposition chamber 50, the second buffer chamber 60 and the unloading chamber 70 are high vacuum chambers.

The loading chamber 20 receives and transfers the substrate 200 which is needing or requiring deposition (pre-deposition substrate) to the pre-process chamber 30. The loading chamber 20 is used as part of the in-line sputtering apparatus 100 so as to avoid the substrate 200 from directly entering and polluting the vacuum area. The loading chamber 20 is vacuum pumped to a preset vacuum degree setting.

The pre-process chamber 30 is positioned adjacent to the loading chamber 20. Cleaning, heating, and other pre-treatments can be done to the substrate 200 in the pre-process chamber 30 before the deposition process. The pre-process chamber 30 connects the loading chamber 20 via one movable gate 90 for keeping or maintaining high vacuum degree and cleaning. Therefore, the pre-process chamber 30 is an independent and high vacuum degree chamber for pre-treatment during the thin film deposition operations.

The first buffer chamber 40 is positioned adjacent to the pre-process chamber 30. The pre-process chamber 30 is positioned between the first buffer chamber 40 and the loading chamber 20. The first buffer chamber 40 is used for storing the substrates 200 needing or requiring deposition process (pre-deposition substrates) when there are some substrates 200 found in the deposition chamber 50. The first buffer chamber 40 avoids collisions between the substrates 200, to ensure proper continuous sputtering and deposition.

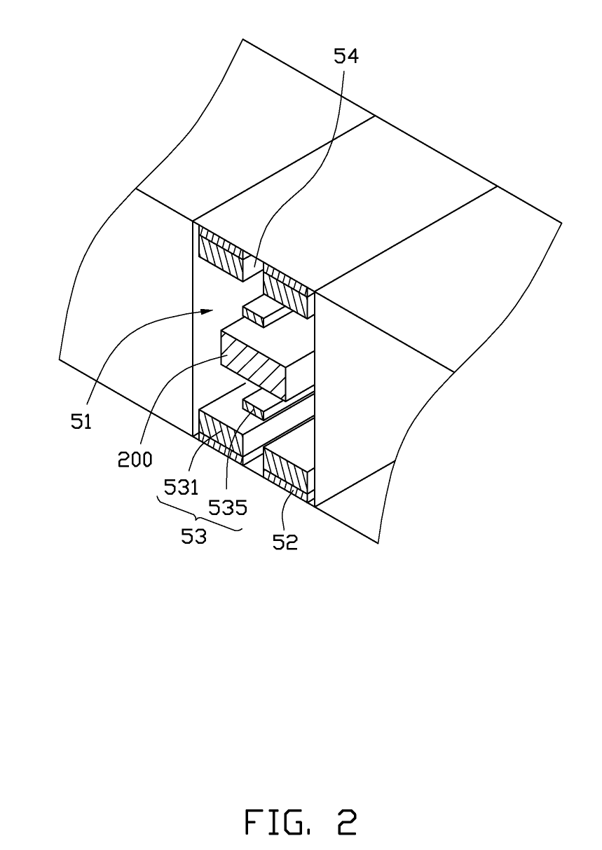

Referring also to FIG. 2, the deposition chamber 50 is positioned adjacent to the first buffer chamber 40. Then, the first buffer chamber 40 is positioned between the pre-process chamber 30 and the deposition chamber 50. The deposition chamber 50 includes two deposition rooms 51, eight electrodes 52 and two target assemblies 53. Each of the deposition rooms 51 includes a deposition area 511 and two installation areas 513 positioned at opposites ends of the deposition area 511. High vacuum will be kept or maintained in the deposition room 51 before deposition for ensuring complete deposition can be achieved. The deposition rooms 51 are filled with inert gas during the deposition. Four electrodes 52 are positioned in each deposition room 51. The four electrodes 52 are divided into two groups; in other words, each group includes two electrodes 52. The two groups of the electrodes 52 are installed on opposite sidewalls of the deposition room 51. In other embodiments, one, or three or more deposition rooms 51 may be included in the deposition chamber 50 for single or multiple operations; at least two electrodes 52 will be positioned on a same side of each deposition room 51; the electrodes 52 positioned on the same side of the deposition room 51 are equidistantly spaced from each other; one movable gate 90 will be positioned between each two adjacent deposition rooms 51 for isolation purposes. The substrates 200 are transferred from one deposition room to another deposition room to pass through the deposition areas 511 for deposition.

Each target assembly 53 is positioned in the installation area 513 of each deposition room 51. Each target assembly 53 includes four targets 531 and two shielding members 535. The four targets 531 are mounted on the four electrodes 52, respectively. A gap 54 exists between two neighboring targets 531 positioned on the same sidewall of the deposition room 51. The targets 531 may be cylindrical or planar. Material(s) of the targets 531 are selected for usage according to real application or purpose(s) desired. The shielding members 535 are positioned in the deposition room 51 adjacent to the edges of the targets 531, between the deposition area 511 and the targets 531. The shielding members 535 are also positioned toward the gaps 54 and parallel to the targets 531. The shielding members 535 shield the substrates 200 from the targets 531 when the substrates 200 “bridge” or has transported to be at close proximity near the gaps 54. The existing shielding members 535 avoid or prevent the atoms from the edges of each two neighboring targets 531 sputtering and depositing upon the substrate 200 at the same time, to ensure an uniform thickness of the film.

Material(s) of the shielding members 535 is chosen according to the actual application requirement or need. In the illustrated embodiment, the shielding members 535 are made of stainless steel, and the projection lengths of the shielding members 535 are equal to the width of the gaps 54, and the widths of the shielding members 535 are equal to that of the substrates 200 for achieving total shielding of the substrates 200 during deposition. The shielding members 535 may be other shapes for ease of adjusting, for example, a thickness of one part of an experimental film (not shown) formed on an experimental substrate 200, which may be greater than that of other parts of the experimental film; as a result, a portion of the shielding member 535 corresponding to that part of the experimental film having greater thickness may also be of a greater width thereof. In other embodiments, the projection lengths of the shielding members 535 aligned on a level line may be greater than the width of the gap 54; the widths of the shielding members 535 maybe greater than the substrates 200; the number of the targets 531 will correspond to the number of the electrodes 52; the arrangement of the targets 531 and the shielding members 535 in the deposition rooms 51 may be arranged according to the different modes of sputtering; for example, the targets 531 may be mounted on the electrodes 52 positioned on the same sidewall for performing single surface sputtering.

The second buffer chamber 60 is positioned adjacent to the deposition chamber 50. The second buffer chamber 60 is positioned between the deposition chamber 50 and the unloading chamber 70. The second buffer chamber 60 is used for storing the substrates 200 and as a cooling chamber after the deposition process. The second buffer chamber 60 also seals the substrates 200 against contact with the atmosphere.

The unloading chamber 70 is positioned adjacent to the second buffer chamber 60 for unloading the substrates 200.

In use, one substrate 200 is transferred to the loading chamber 20. The substrate 200 passes through the pre-process chamber 30 and the first buffer chamber 40 in that order, and then reaches the deposition area 511 of the deposition chamber 50. The glow discharge will occur in the deposition chamber 50 because a high voltage is applied between the electrodes 52. Inert gas will be initially ionized to form plasma. Ions of the plasma will collide randomly with the targets 531. Atoms of the targets 531 are collided by the ions of the plasma and sputtered off to be deposited upon the substrate 200. A thin film (not shown) with a certain thickness comprising of the atoms of the targets 531 will be formed on the substrate 200. The shielding members 535 will reduce the ratio of the atoms from the ends of the targets 531 (as compared to atoms from other portions of the targets 531) being sputtered onto the substrate 200 because the shielding members 535 are positioned between the targets 531 and the deposition areas 511 close to the gaps 54. Then any unwanted atoms from the edges of the targets 531 will be sputtered on the shielding members 535. A thickness of the shielding member 535 decreases from the middle towards the ends of the shielding member 535. After deposition process, the substrate 200 will be transferred to the second buffer chamber 60 and to the unloading chamber 70.

The shielding members 535 of the in-line sputtering apparatus 100 are positioned between the targets 531 and the deposition areas 511 close to the gaps 54. The shielding members 535 reduce the ratio of the atoms from the ends of the targets 531 (as compared to the atoms from other portions of the targets 531) sputtering onto the substrate 200 and significantly improve the uniformity of thickness of the film formed on the substrate 200.

While various embodiments have been described and illustrated, the disclosure is not to be construed as being limited thereto. Various modifications can be made to the embodiments by those skilled in the art without departing from the true spirit and scope of the disclosure as defined by the appended claims.

What is claimed is:

1. An in-line sputtering apparatus, comprising:
a loading chamber, a deposition chamber and an unloading chamber arranged in that order, the deposition chamber comprising:
at least one deposition room defining a deposition area, a plurality of electrodes positioned oppositely on the sidewalls of the deposition room, the electrodes on the same sidewall are spaced from each other, and at least one target assembly comprising a plurality of targets and at least one shielding member, wherein each target is mounted on one electrode and away from the deposition area, a gap exists between each two neighboring targets, and each shielding member is positioned toward one gap for shielding the sputtering of atoms from the edges of two neighboring targets between the targets and the deposition area.

2. The in-line sputtering apparatus of claim 1, wherein a projection length of the shielding member is equal to a width of the gap.

3. The in-line sputtering apparatus of claim 1, wherein a projection length of the shielding members is greater than a width of the gap.

4. The in-line sputtering apparatus of claim 1, wherein the at least one shielding member is positioned parallel to the targets.

5. The in-line sputtering apparatus of claim 1, wherein the in-line sputtering apparatus further comprises a first buffer chamber positioned between the loading chamber and the deposition chamber.

6. The in-line sputtering apparatus of claim 5, wherein the in-line sputtering apparatus further comprises a second buffer chamber positioned between the unloading chamber and the deposition chamber.

7. The in-line sputtering apparatus of claim 6, wherein the in-line sputtering apparatus further comprises a pre-process chamber positioned between the first buffer chamber and the loading chamber.

8. The in-line sputtering apparatus of claim 6, wherein the in-line sputtering apparatus further comprises a plurality of movable gates, the movable gates are positioned between the loading chamber and the pre-process chamber, the pre-process chamber and the first buffer chamber, the first buffer chamber and the deposition chamber, the deposition chamber and the second buffer chamber, the second buffer chamber and the unloading chamber.

9. The in-line sputtering apparatus of claim 6, wherein one movable gate is positioned between each two neighboring deposition rooms.

10. The in-line sputtering apparatus of claim 1, wherein each deposition room further comprises a plurality of installation areas communicating with the deposition area, the at least one target assembly is mounted in the installation areas.

11. The in-line sputtering apparatus of claim 1, wherein the plurality of targets are made of stainless steel.
